(19) United States
(12) Patent Application Publication
(10) Pub. No.: US 2022/0350862 A1
(43) Pub. Date: Nov. 3, 2022

(54) LOW-LATENCY SUBSPACE PURSUIT APPARATUS AND METHOD FOR RECONSTRUCTING COMPRESSIVE SENSING

(71) Applicant: POSTECH RESEARCH AND BUSINESS DEVELOPMENT FOUNDATION, Pohang-si (KR)

(72) Inventors: Young Joo LEE, Pohang-si (KR); Young Seok KIM, Seongnam-si (KR); Seung Woo HONG, Busan (KR)

(21) Appl. No.: 17/607,847

(22) PCT Filed: Nov. 26, 2020
(86) PCT No.: PCT/KR2020/016982

§ 371 Date: Oct. 29, 2021

(30) Foreign Application Priority Data
Nov. 11, 2020 (KR) 10-2020-0150399

(51) Int. Cl. G06F 17/16; H03M 13/37; H03M 13/00

(52) U.S. Cl. CPC G06F 17/16; H03M 13/3746; H03M 13/6502

(57) ABSTRACT

A subspace pursuit apparatus for compressive sensing reconstruction includes: a first inner product unit configured to calculate a correlation between a residual vector and column vectors of a sensing matrix by calculating an inner product of them; a first sorting unit coupled to the first inner product unit and configured to select K column vector indices having highest correlations, where K is a sparsity level; a second inner product unit configured to calculate a matrix for calculating a pseudo-inverse matrix required for solving a least-squares from the sensing matrix to store in the Gram matrix buffer; a Cholesky inversion unit configured to perform a Cholesky decomposition of the matrix stored in the Gram matrix buffer and calculate an inverse of a decomposed matrix; and a sparse solution estimator configured to estimate the sparse solution from a matrix value of the matrix based on the inverse of the decomposed matrix.

### TECHNICAL FIELD

The present disclosure relates to a low-latency subspace pursuit apparatus and method for a compressive sensing reconstruction which enables to reconstruct a sparse vector effectively from a measurement vector or an input signal sensed in a compressive sensing.

### BACKGROUND

A compressive sensing (CS) enables a sampling of a sparse signal, at a frequency lower than a Nyquist frequency, that can be represented by fewer coefficients in a specific domain, i.e., a sparsifying domain.

In the case of a Nyquist sampling, a signal may be sampled at a frequency higher than twice a highest frequency of the signal and then be compressed by choosing only some portion of the coefficients through a suitable transformation. In case of the compressive sensing, however, a compressed measurement vector may be obtained in a sensing stage instead of sampling the signal and then performing the compression.

The measurement vector may be expressed by a product of a measurement matrix or a sensing matrix and a sparse vector as shown in FIG. 1. An algorithm for finding the sparse vector from the sensed measurement vector is a compressive sensing reconstruction algorithm.

A conventional compressive sensing reconstruction typically employs a greedy algorithm for a fast reconstruction, and an orthogonal matching pursuit (OMP) is one of the most widely used algorithms among them.

The OMP is an iterative greedy algorithm which selects a column vector having a largest correlation between a residual vector and a column vector of the sensing matrix as a support vector in each iteration. A residual vector is projected to a generation space, i.e., a span, of selected support vectors to estimate the sparse vector, i.e., a sparse solution, and then the residual vector is updated. That is, the residual vector has a same value as the measurement vector in a first iteration in the OMP but, as iterations proceeds, the value contributed by the selected support vector is removed. By repeating this process, the position and value of the sparse vector are finally reconstructed.

Vector operations included in the OMP or calculations of pseudo-inverse matrices for solving a least-squares problem (LSP) may cause a long delay time when they are implemented in software. Many hardware accelerators have been proposed to solve this problem.

In the OMP, each iteration may add one support vector, which is not corrected in subsequent iteration operations. Thus, there may arise a problem of an error propagation caused by the support vector incorrectly determined in the past.

A subspace pursuit (SP) is one of the most widely used algorithms proposed to solve this problem. The SP selects K support vectors in each iteration, where ‘K’ is a number of sparse factors, i.e., sparsities, of sparse vectors. Selected K support vectors are combined with the K support vectors selected in the past, and K support vectors with a highest contribution are selected among up to 2K support vectors. An incorrectly selected support vector can be corrected through this process.

Currently, however, there is no hardware implementation that can support the subspace pursuit. Hardware for the OMP cannot be used for the subspace pursuit and needs some modification to use for the subspace pursuit because the hardware is not parallelized and may reveal a long delay time.

### SUMMARY

To solve the problems, provided are low-latency subspace pursuit apparatus and method for compressive sensing reconstruction which can reconstruct a sparse vector from a measurement vector or an input signal in the compressive sensing.

Provided are low-latency subspace pursuit apparatus and method for compressive sensing reconstruction which use a subspace pursuit as a compressive sensing reconstruction algorithm, use a Cholesky decomposition to solve a least-squares problem, and employ parallel computing hardware to support the Cholesky decomposition.

Provided are low-latency subspace pursuit apparatus and method for compressive sensing reconstruction which use a subspace pursuit as a compressive sensing reconstruction algorithm, and skip the least-squares problem one by one and perform a next iteration during a process of updating a residual vector to search a correlation in parallel with a Cholesky decomposition module.

According to an aspect of an exemplary embodiment, a subspace pursuit apparatus for compressive sensing reconstruction, includes: a first inner product unit of type 1 configured to calculate a correlation between a residual vector stored in a residual calculation unit (RCU) and column vectors of a sensing matrix stored in a sensing matrix memory by calculating an inner product of the residual vector and the column vectors; a first sorting unit coupled to an output terminal of the first inner product unit of type 1 and configured to receive correlation values calculated by the first inner product unit and select K column vector indices having highest correlations, where K is a sparsity level; a second inner product unit configured to calculate a matrix for calculating a pseudo-inverse matrix required for solving a least-squares problem (LSP) during a sparse solution estimation process from the sensing matrix stored in the sensing matrix memory to store in the Gram matrix buffer; a Cholesky inversion unit configured to perform a Cholesky decomposition of the matrix stored in the Gram matrix buffer and calculate an inverse of a decomposed matrix; and a sparse solution estimator configured to estimate the sparse solution from a matrix value of the matrix based on the inverse of the decomposed matrix.

In an embodiment, the first sorting unit may select K most dominant supports from a union of a newly selected supports set and an existing supports set. The residual calculation unit may update the residual vector based on a union support set including the K selected supports and a sparse solution estimation result from the sparse solution estimator.

In an embodiment, the residual calculation unit may generate an approximate residual vector by skipping a calculation of a Cholesky inverse matrix when the residual calculation unit updates the residual vector. The approximate residual vector may be used in a support search process

In an embodiment, the Cholesky inversion unit may include a plurality of processing element (PE) groups each comprising a plurality of PEs. Each of the PE groups may generate a plurality of values in parallel when the Cholesky decomposition is performed, and the plurality of values may be generated as their dependencies in respective PE groups are resolved.

In an embodiment, the Cholesky decomposition for a last LSP of each PE group may be skipped and be approximated based on the Cholesky decomposition for a first LSP of a corresponding PE group, so that a delay time is reduced and a next iteration is performed based on results of the sparse solution estimation process and the support search process.

In an embodiment, the Cholesky decomposition for a second LSP of each PE group may be performed in parallel with the support search process of the next iteration for the next iteration.

In an embodiment, the Cholesky decomposition module implementing the Cholesky inversion unit and the sparse solution estimator may include: the Gram matrix buffer connected to each of a plurality of operation modules of each PE group; a D buffer configured to store an output value of each PE group; and a buffer controller configured to store control operations of the Gram matrix buffer and the D buffer.

In an embodiment, each of the plurality of operation modules may include internal buffers configured to store, in a location designated by the buffer controller, a decomposed matrix resulting from the Cholesky decomposition and an inverse matrix element value obtained by calculating an inverse matrix of the decomposed matrix.

According to another aspect of an exemplary embodiment, a subspace pursuit method for compressive sensing reconstruction, includes: calculating, by a first inner product unit of type 1, a correlation between a residual vector stored in a residual calculation unit (RCU) and column vectors of a sensing matrix stored in a sensing matrix memory by calculating an inner product of the residual vector and the column vectors; receiving, by a first sorting unit coupled to an output terminal of the first inner product unit, correlation values calculated by the first inner product unit to select K column vector indices having highest correlations, where K is a sparsity level; calculating, by a second inner product unit coupled to the sensing matrix memory, a matrix for calculating a pseudo-inverse matrix required for solving a least-squares problem (LSP) during a sparse solution estimation process to store in a Gram matrix buffer; performing, by a Cholesky inversion unit coupled to the Gram matrix buffer, a Cholesky decomposition of the matrix stored in the Gram matrix buffer and calculating an inverse of a decomposed matrix; and estimating, by a sparse solution estimator, the sparse solution from a matrix value of the matrix stored in the Gram matrix buffer based on the inverse of the decomposed matrix.

According to another aspect of an exemplary embodiment, a subspace pursuit method for compressive sensing reconstruction, includes: (a) measuring a correlation between a sensing matrix and a residual vector; (b) receiving correlation values to select K column vector indices having highest correlations to set a support set, where K is a sparsity level; (c) pursuing a sparse vector by a least-squares method based on the support set; (d) updating the residual vector based on a pursued sparse vector; (e) estimating the sparse vector by the least-squares method based on a reset support set when the Cholesky decomposition being performed in parallel is completed after an iteration of operations (a) and (b) during an iteration process; (f) setting K numbers having large sparse vectors pursued in the operation (e) as a support set; (g) approximating the residual vector based on the support set including the K supports set in the operation (f); and (h) sequentially repeating the operations (a), (b), (e), (f), and (g) while performing the Cholesky decomposition in parallel again until the residual vector is smaller than a threshold value.

In an embodiment, the operation (e) may be performed based on the correlation and the calculation result of the Cholesky inversion unit.

In an embodiment, the operation (f) may include: selecting K most dominant supports from a union of a newly selected supports set and an existing supports set.

In an embodiment, a plurality of values may be generated in parallel by a plurality of processing element (PE) groups each comprising a plurality of PEs in a Cholesky inversion unit, and the plurality of values may be generated as their dependencies in respective PE groups are resolved.

In an embodiment, the Cholesky decomposition for a last least-squares problem (LSP) of each PE group may be skipped and is approximated based on the Cholesky decomposition for a first LSP of a corresponding PE group, so that a next iteration may be performed based on results of an estimation process for the sparse vector or sparse solution and the support search process.

The subspace pursuit apparatus and method for compressive sensing reconstruction described above can reconstruct the sparse vector from the measurement vector or the input signal sensed in the compressive sensing.

The present disclosure enables to provide a low-latency subspace pursuit processor that can be effectively utilized in a channel estimation and symbol detection, for example, in a wireless communications system employing the compressive sensing and a sensor network for analyzing a biometric signal.

### BRIEF DESCRIPTION OF THE DRAWINGS

In order that the disclosure may be well understood, there will now be described various forms thereof, given by way of example, reference being made to the accompanying drawings, in which:

FIG. 1 illustrates an example of a measurement vector model in conventional compressive sensing;

FIG. 2 is a block diagram showing an overall architecture of a subspace pursuit apparatus for compressive sensing reconstruction according to an exemplary embodiment of the present disclosure;

FIG. 3 is a block diagram of a Cholesky decomposition module in the subspace pursuit apparatus for compressive sensing reconstruction of FIG. 2;

FIG. 4 is a block diagram of a processing element in the Cholesky decomposition module of FIG. 3;

FIG. 5 is an exemplary circuit diagram of an internal MAC unit that may be employed in the processing element of FIG. 4;

FIG. 6 illustrates calculation operations performed sequentially by the Cholesky decomposition module of FIG. 3;

FIG. 7 illustrates a process of estimating the sparse vector by combining a previous support vector and a new support vector in the subspace pursuit apparatus according to an exemplary embodiment;

FIG. 8 illustrates a process of updating a residual vector following a sparse vector estimation process of FIG. 7;

FIG. 9 shows an exemplary pseudo code of a basic algorithm for a compressive sensing reconstruction process of the subspace pursuit apparatus of FIG. 2;

FIG. 10 shows an exemplary pseudo code of a modified residual vector calculation process that can be employed in the basic algorithm of FIG. 9;

FIG. 11 is a flowchart showing a compressive sensing reconstruction process of the subspace pursuit apparatus of FIG. 2;

FIG. 12 is a graph illustrating a theoretical block error rate of a parallel subspace pursuit processor according to an exemplary embodiment of the present disclosure compared with that of a comparative example; and

FIG. 13 illustrates a processing speed of the subspace pursuit apparatus for compressive sensing reconstruction according to an exemplary embodiment of the present disclosure together with comparative examples.

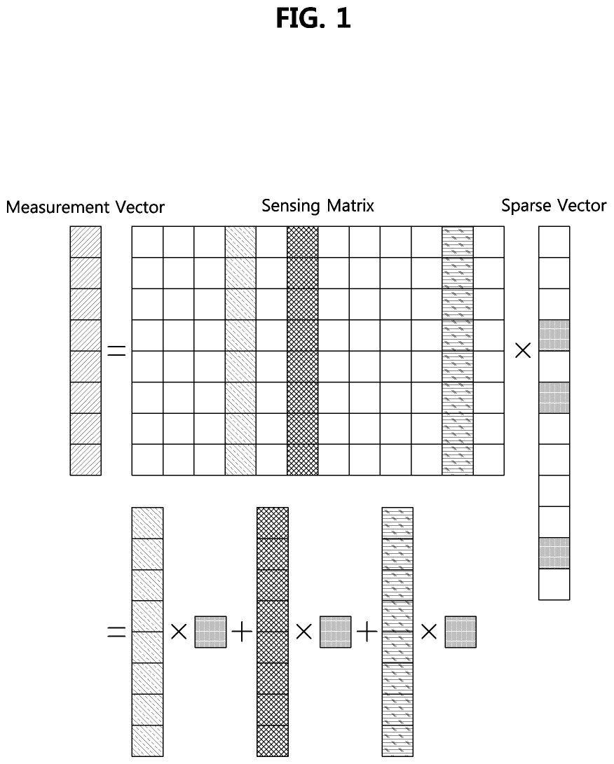

The drawings described herein are for illustration purposes only and are not intended to limit the scope of the present disclosure in any way.

### DETAILED DESCRIPTION

For a more clear understanding of the features and advantages of the present disclosure, exemplary embodiments of the present disclosure will be described in detail with reference to the accompanied drawings. However, it should be understood that the present disclosure is not limited to particular embodiments disclosed herein but includes all modifications, equivalents, and alternatives falling within the spirit and scope of the present disclosure.

The terminologies including ordinals such as “first” and “second” designated for explaining various components in this specification are used to discriminate a component from the other ones but are not intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies are used herein for the purpose of describing particular exemplary embodiments only and are not intended to limit the present disclosure. The singular forms include plural referents as well unless the context clearly dictates otherwise. Also, the expressions “comprises,” “includes,” “constructed,” “configured” are used to refer a presence of a combination of stated features, numbers, processing steps, operations, elements, or components, but are not intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Prior to describe exemplary embodiments in detail with reference to the drawings, major features of the present disclosure will be described briefly as follows.

The present disclosure uses a parallel Cholesky decomposition module to solve a least-squares problem for estimating a sparse vector in a course of performing a subspace pursuit (SP) which is one of the compressive sensing (CS) reconstruction algorithms. In addition, the present disclosure uses a forwarded approximate residual vector in a support selection process.

The present disclosure performs a Cholesky decomposition to calculate a pseudo-inverse matrix for solving the least-squares problem (LSP) in consideration that the Cholesky decomposition can be performed in a linear time in case that the calculation is performed in parallel by adding hardware resources.

According to the present disclosure, the SP algorithm includes a process of selecting K most dominant supports from a union of a newly selected supports set and an existing supports set, where ‘K’ is a sparsity level, and a process of updating the residual vector based on the support set determined through the support selection process. Also, both the successive processes are based on the least-squares problems.

In addition, considering that a next iteration can be initiated only when results of two consecutive processes are derived, the present disclosure skips a last LSP and approximates a result of the last LSP with that of a first LSP to reduce a delay time.

On the other hand, since the result of the Cholesky decomposition accompanying the second LSP process is required for a next iteration, the second LSP should be performed inevitably. However, the Cholesky decomposition may be performed in parallel with the support search process.

Hereinbelow, preferred embodiments of the present disclosure will be described in more detail with reference to the accompanying drawings.

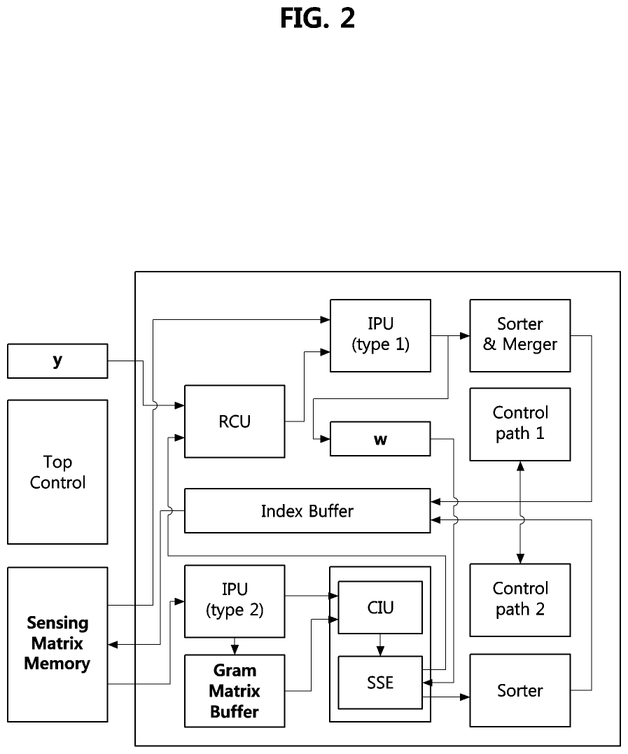

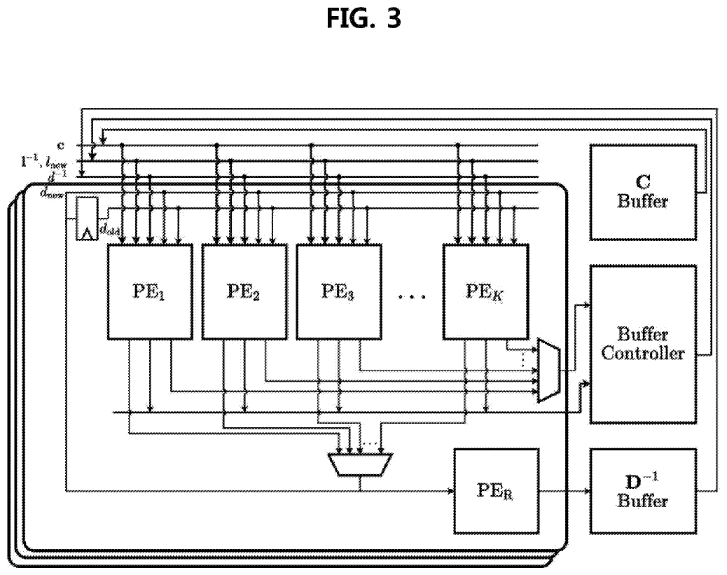

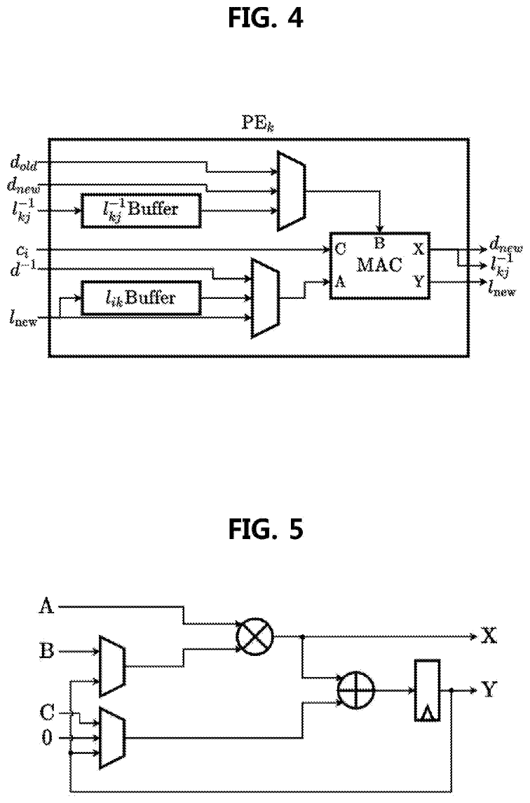

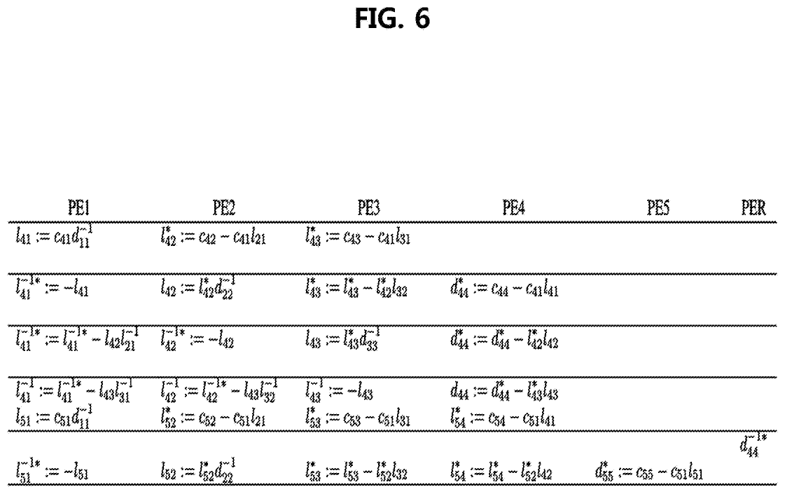

FIG. 2 is a block diagram illustrating an overall architecture of a subspace pursuit apparatus for compressive sensing reconstruction according to an exemplary embodiment of the present disclosure. FIG. 3 is a block diagram of a Cholesky decomposition module in the subspace pursuit apparatus compressive sensing reconstruction of FIG. 2. FIG. 4 is a block diagram of a processing element in the Cholesky decomposition module of FIG. 3. FIG. 5 is an exemplary circuit diagram of an internal MAC unit that may be employed in the processing element of FIG. 4. FIG. 6 illustrates calculation operations performed sequentially by the Cholesky decomposition module of FIG. 3.

Referring to FIG. 2, the overall architecture of the subspace pursuit (SP) apparatus according to the present embodiment includes a sensing matrix memory (SMM) for storing a sensing matrix and a processor. The processor includes a residual calculation unit (RCU), a first inner product unit (IPU) of type 1, a sorter-and-merger (hereinbelow, referred to as “first sorting unit” also), an index buffer, a second inner product unit of type 2, a Gram matrix buffer (GMB), a Cholesky inversion unit (CIU), a sparse solution estimator (SSE), a sorter (hereinbelow, referred to as “second sorting unit” also), and first and second control path. The sensing matrix memory (SMM) will be referred to as the sensing matrix unit also.

The subspace pursuit apparatus may include a top control or top control sequencer which receives, stores, and executes system microcodes or instructions to control an operation of a control sequencer. Also, the subspace pursuit apparatus may include a signal receiving unit for receiving a signal from an external device or a signal transfer unit for transferring a signal inside the apparatus. In addition, the processor and the memory may be connected through a system bus.

More specifically, the residual calculation unit (RCU) calculates and stores the residual vector corresponding to an estimation result of the sparse solution estimator (SSE). The residual calculation unit (RCU) may store, as the residual vector, a difference between an observation value input through a predetermined buffer or memory and the estimation result corresponding to the observation value.

The first inner product unit of type 1 calculates an inner product of the residual vector stored in the residual calculation unit (RCU) and column vectors of the sensing matrix stored in the sensing matrix memory (SMM) to obtain a correlation between them.

Correlation values calculated by the first inner product unit of type 1 are transferred to the first sorting unit coupled to an output terminal of the first inner product unit, so that the first sorting unit selects K column vector indices having the highest correlation. Here, ‘K’ may be a sparsity level. The selection result of the first sorting unit is stored in the index buffer to be used to update data stored in the sensing matrix unit.

The second inner product unit of type 2 calculates a matrix for calculating a pseudo-inverse matrix required for solving the least-squares problem (LSP) during a process of estimating a sparse solution from the sensing matrix stored in the sensing matrix unit to store in the Gram matrix buffer (GMB).

The Cholesky inversion unit is coupled to the Gram matrix buffer (GMB) and calculates a Cholesky inverse matrix of the matrix stored in the Gram matrix buffer. The Cholesky inversion unit (CIU) may perform a unit operation in synchronicity with a signal from the second inner product unit of type 2.

The sparse solution estimator (SSE) estimates the sparse solution through a least-squares method from the Gram matrix values stored in the Gram matrix buffer based on a calculation result of the Cholesky inversion unit (CIU). An estimation result of the sparse solution estimator (SSE) is transferred to the residual computation unit (RCU).

Also, the sparse solution estimator (SSE) may estimate the sparse solution based on the K column vector indices selected by the first inner product unit of type 1. In such a case, the processor may include a buffer (w) suitable for transferring the selection result of the first inner product unit of type 1 to the sparse solution estimator (SSE).

The second sorting unit (i.e. the sorter) stores an index of the sparse solution which is the estimation result of the sparse solution estimator (SSE) in the index buffer.

The index buffer stores the column vector index from the first sorting unit and the sparse solution index from the second sorting unit. The index buffer causes a prescribed number of memory areas determined by a preset rule to be created in the sensing matrix unit so as to reduce a computing amount of the processor and increase the speed of the processor.

According to the present embodiment, the Cholesky decomposition module in the processor of the subspace pursuit apparatus generally includes the Cholesky inverse unit (CIU) suitable for performing the Cholesky decomposition of a matrix stored in a Gram matrix buffer (GMB) and the sparse solution estimation module (SSE) suitable for estimating the sparse solution of a Gram matrix stored in the Gram matrix buffer (GMB) based on a calculation result of the Cholesky inverse unit (CIU).

As shown in FIG. 3, the Cholesky decomposition module includes a plurality of processing element (PE) groups, a C-buffer (C buffer), a D-buffer (D⁻¹ buffer), and a buffer controller. In FIG. 3, the C-buffer is a Gram matrix buffer (GMB) and ‘C’ denotes a Gram matrix.

There may be a total of K/4 processing element (PE) groups, and each processing element (PE) group includes K processing elements (PEs). In more detail, each of the processing element groups includes a plurality of processing elements (PE1-PEK, and PER) and a multiplexer (MUX). In the Gram matrix buffer, one row vector is passed to the processing element groups in each iteration.

The output values of the processing elements (PEs) are the Cholesky decomposition values of each row vector, and includes elements dᵢⱼ⁻¹ of an inverse matrix of a diagonal matrix, elements lᵢⱼ of a lower triangular matrix, and elements lᵢⱼ⁻¹ of an inverse matrix of the lower triangular matrix. The element values of the inverse matrix of the diagonal matrix is stored in the D⁻¹ buffer, and the element values of the lower triangular matrix and the inverse matrix of lower triangular matrix inverse matrix are transferred to the buffer controller to be stored in buffers of another processing elements as shown in FIG. 4. These values can be reused by the other processing element groups or the original processing element group. Also, temporary values exemplified in FIG. 6 which are generated during the calculations are also broadcast to all the processing elements in the processing element group in order to transfer to the other processing elements.

Lines over of the processing elements PE1-PEK shown on a top portion of the drawing indicate propagated values, and some of the propagated values are used in each of the processing elements.

The internal structure of each processing element is shown in FIG. 4. Referring to FIG. 4, the processing element PEK includes two buffers, two accumulators, and a multiply-and-accumulate (MAC) unit. The values stored in the buffers depend on the buffer controller. The MAC unit may correspond to an arithmetic logic unit (ALU) of a general processor.

An exemplary circuit diagram of the MAC unit is illustrated in FIG. 5. Referring to FIG. 5, the MAC unit includes two accumulators, a multiplier, and an adder. The MAC unit may be configured to output X and Y for inputs A, B, C, and 0, for example.

An example of operation timings of the Cholesky decomposition module according to the present embodiment is shown in FIG. 6, which shows how the fourth row vector transferred to the processing element group by the Gram matrix buffer is calculated sequentially.

Before the fourth row vector is received, the Cholesky decomposition of the matrix composed of a first to third row vectors is completed already, and the calculation of the element values of the inverse matrix is completed also. The calculated values are stored in the buffers of the processing elements at appropriate positions by the buffer controller.

In FIG. 6, the values presented in upper portions of the rows of the table are those generated by a first processing element group, and the values presented in lower portions of the rows of the table are those generated by another processing element group. Since the processing element groups are configured in parallel according to the present embodiment, the decomposition of a fifth row vector may start even though the decomposition of a fourth row vector is not completed yet. The timing at which the decomposition of the fifth row vector starts may be determined in consideration of time for all data required for decomposing the fifth row vector to be prepared.

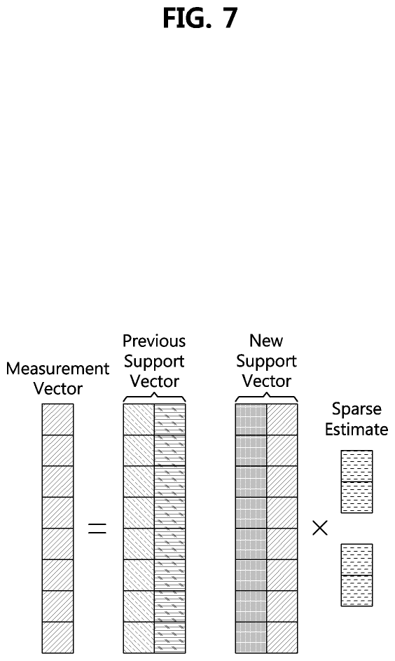

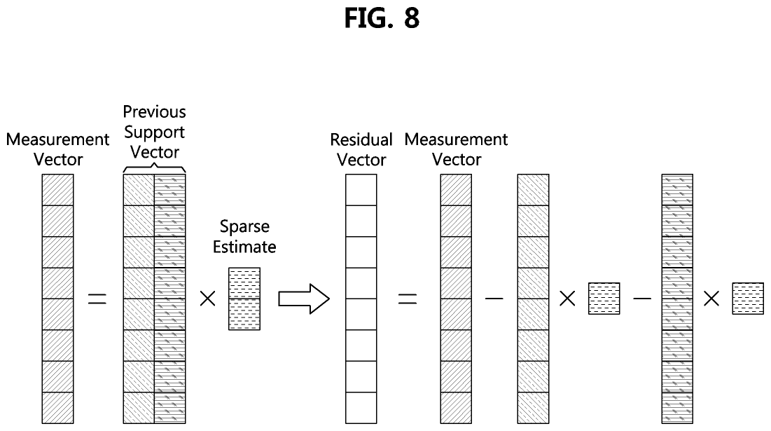

FIG. 7 illustrates a process of estimating the sparse vector by combining a previous support vector and a new support vector in the subspace pursuit apparatus according to the present embodiment. FIG. 8 illustrates a process of updating the residual vector following the sparse vector estimation process of FIG. 7.

As shown in FIG. 7, the subspace pursuit apparatus combines the support vector determined in a previous iteration and the new support vector selected in a current iteration to estimate the sparse vector. In case of the example shown in FIG. 7, the sparsity level K is 2. In other words, only K (i.e., two) largest sparse vectors remains after the estimation.

The process of updating the residual vector corresponds to the process of modifying the residual vector at the end of the subspace estimation process.

In detail, as shown in FIG. 8, only K support vectors are left through the support vector estimation shown in the sparse estimate process, and the sparse vector properly describing the measurement vector is found by solving the least-squares problem (LSP) from the previous support vector remaining after the support vector estimation. Then, as the residual vector is updated by a difference between the measurement vector and the reconstructed sparse vector.

The sparse vector estimation process described above can be solved by the least-squares method for an overdetermined system of equations. The least-squares method requires a computation of a pseudo-inverse matrix, which is performed in the Cholesky decomposition module.

As described above, the accurate residual vector, which may be calculated by sequentially performing the processes shown in FIGS. 7 and 8, is calculated in the present embodiment by approximating the sparse vector value of a 2K-dimension generated by the process of FIG. 7 by the sparse vector value of a K-dimension generated by the process of FIG. 8. Accordingly, the present embodiment can simplify the calculation and greatly reduce the delay time.

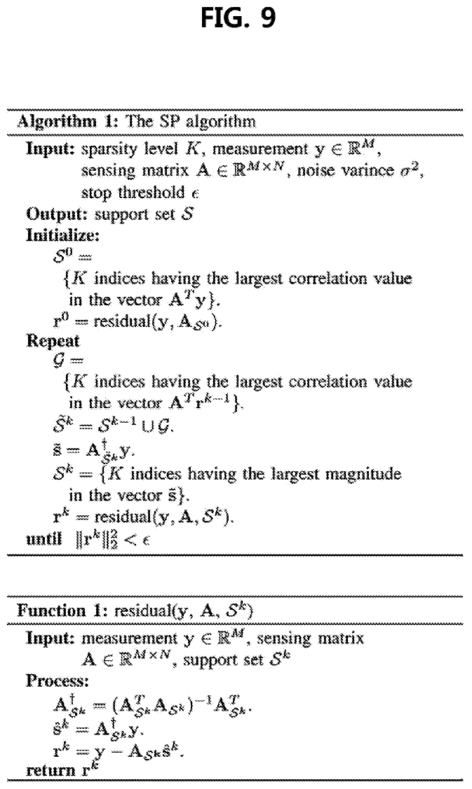

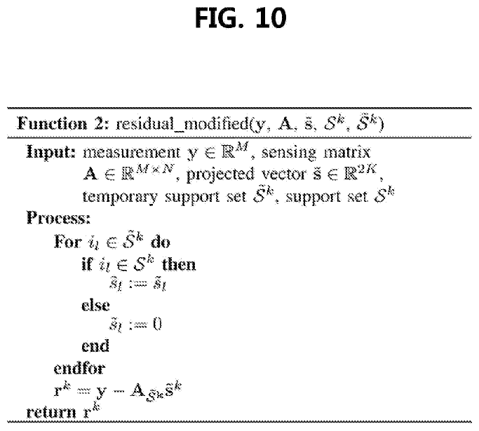

FIG. 9 shows an exemplary pseudo code of a basic algorithm for the compressive sensing reconstruction process of the subspace pursuit apparatus of FIG. 2. FIG. 10 shows an exemplary pseudo code of a modified residual vector calculation process that can be employed in the basic algorithm of FIG. 9.

The algorithm shown in FIG. 9 is a basic subspace pursuit algorithm that can be employed in the subspace pursuit apparatus for compressive sensing reconstruction according to the present embodiment.

The process of using the least-squares method in the subspace pursuit algorithm is handled by the Cholesky decomposition module of FIG. 3. Also, the residual vector approximation is processed by replacing a function, residual vector(y, A, Sk), shown in FIG. 9, with a modified residual vector calculating function, residual_modified( ), shown in FIG. 10.

That is, when calculating the residual vector through the process shown in FIG. 10, the Cholesky decomposition module of FIG. 3 is skipped and the residual vector is transferred to the first inner product unit of type 1 shown in FIG. 2, and then the next iteration is started.

On the other hand, the Cholesky decomposition module of FIG. 3 has a structure that decomposes the entire Gram matrix while adding row vectors one by one. For the Cholesky decomposition of the Gram matrix consisting of a new support vector selected as a result of the sparse vector pursuit process of FIG. 7 and the Gram matrix extended by the support vector added thereafter, it may be desirable for reducing a delay time to perform the decomposition of the Gram matrix generated as a result of the sparse vector pursuit process of FIG. 7 in advance.

Therefore, the residual vector is approximated by the residual vector calculation method of FIG. 10 and transferred to the first inner product unit of type 1 shown in FIG. 2 through the residual calculation unit. When a next iteration starts, the Cholesky decomposition of FIG. 3 may simultaneously start the Cholesky decomposition of the Gram matrix before the next support vector is added.

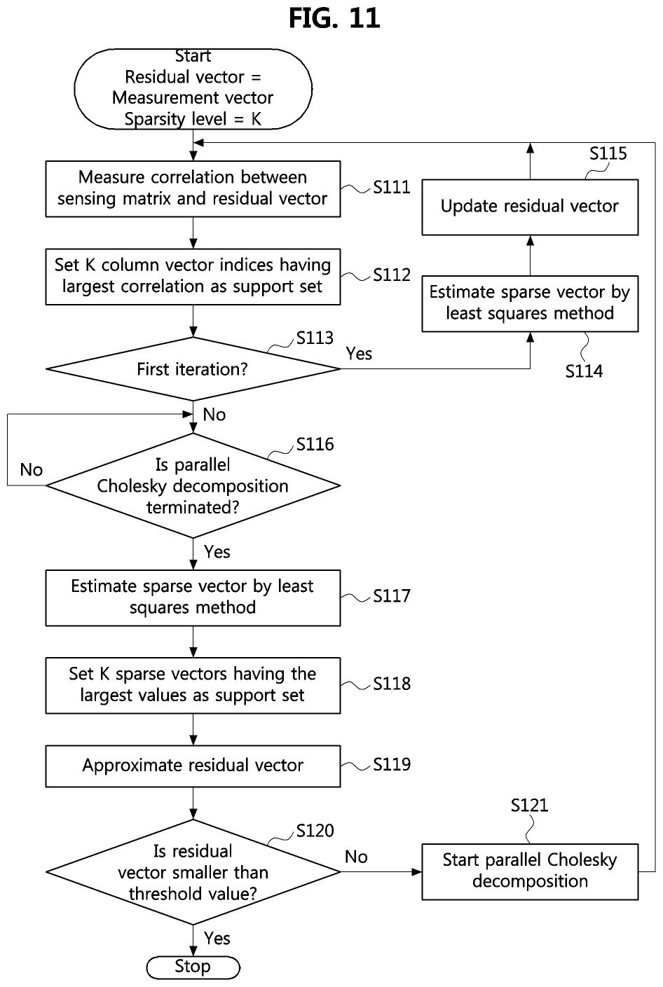

FIG. 11 is a flowchart showing a compressive sensing reconstruction process of the subspace pursuit apparatus of FIG. 2.

Referring to FIG. 11, in the subspace pursuit method for compressive sensing reconstruction according to the present embodiment, a correlation between a sensing matrix and the residual vector is first measured (S111).

Next, based on the correlation values calculated through the correlation measurement, K column vector indices having the largest correlation are set as the support set (S112), where K is the sparsity level.

Afterwards, it is determined whether it is a first iteration or not (S113). If it is determined to be the first iteration in the operation S113), the sparse vector is pursued by the least-squares method based on the support set (S114).

Subsequently, the residual vector is updated based on the pursued sparse vector (S115). The first iteration is performed through the operations S111-S115.

If it is determined not to be the first iteration in the operation S113 after the operations S111 and S112 during the iteration after the operation S115, it is determined whether the Cholesky decomposition being performed in parallel is terminated or not (S116). If it is determined that the parallel Cholesky decomposition is terminated, a sparse vector is pursued by the least-squares method based on an updated support set (S117).

Next, indices of K sparse vectors having the largest values among the sparse vectors pursued in the operation S117 are set as the support set (S118).

Then, the residual vector is approximated based on the support set including K supports set in the operation S118 (S119).

Until the residual vector is smaller than a stop threshold (S120), the Cholesky decomposition is performed again in parallel (S121) and some of the operations S111, S112, S113, and S116 through S120 are repeated carried out sequentially.

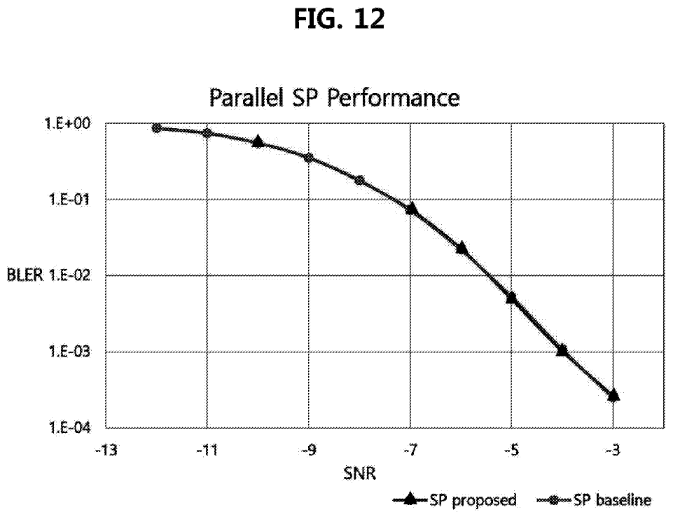

FIG. 12 is a graph illustrating a theoretical block error rate of the parallel subspace pursuit processor according to an exemplary embodiment of the present disclosure compared with that of a comparative example.

Comparing the sparse vector reconstruction performance, in terms of a signal-to-noise ratio (SNR), of the parallel subspace pursuit processor of the present embodiment with the comparative example, the parallel subspace pursuit processor of the present embodiment exhibits an almost identical performance with the comparative example of the subspace pursuit baseline even though the parallel subspace pursuit processor of the present embodiment employs the approximate residual vector.

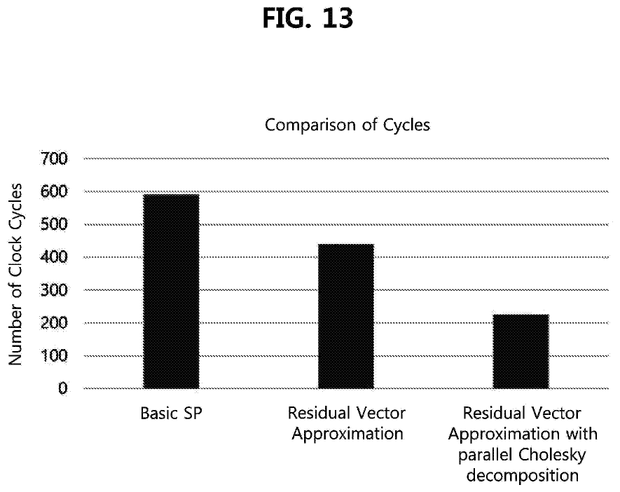

FIG. 13 illustrates a processing speed of the subspace pursuit apparatus for compressive sensing reconstruction according to an exemplary embodiment of the present disclosure together with comparative examples.

In FIG. 13, a left bar represents a number of clock cycles elapsed in case that the basic subspace pursuit algorithm is implemented in hardware, the middle bar represents the number of clock cycles elapsed when the residual vector approximation of FIG. 10 is applied in addition to the basic subspace pursuit algorithm, and the right bar represents the number of clock cycles elapsed according to an exemplary embodiment of the present disclosure in which the parallel Cholesky decomposition is further applied to the subspace pursuit algorithm and the residual vector approximation. It can be seen that the method according to the exemplary embodiment of the present disclosure represented by the right bar achieves a reduction in a delay time by about 62% compared with the comparative example of the basic subspace pursuit algorithm represented by the left bar.

While exemplary embodiments have been described above in detail, it should be understood that various modifications and alterations can be made without departing from the spirit and scope of the present disclosure set forth in the appended claims.

What is claimed is:

1. A subspace pursuit apparatus for compressive sensing reconstruction, comprising:
a first inner product unit of type 1 configured to calculate a correlation between a residual vector stored in a residual calculation unit (RCU) and column vectors of a sensing matrix stored in a sensing matrix memory by calculating an inner product of the residual vector and the column vectors;
a first sorting unit coupled to an output terminal of the first inner product unit of type 1 and configured to receive correlation values calculated by the first inner product unit and select K column vector indices having highest correlations, where K is a sparsity level;
a second inner product unit configured to calculate a matrix for calculating a pseudo-inverse matrix required for solving a least-squares problem (LSP) during a sparse solution estimation process from the sensing matrix stored in the sensing matrix memory to store in the Gram matrix buffer;
a Cholesky inversion unit configured to perform a Cholesky decomposition of the matrix stored in the Gram matrix buffer and calculate an inverse of a decomposed matrix; and
a sparse solution estimator configured to estimate the sparse solution from a matrix value of the matrix based on the inverse of the decomposed matrix.

2. The subspace pursuit apparatus for compressive sensing reconstruction of claim 1, wherein the first sorting unit selects K most dominant supports from a union of a newly selected supports set and an existing supports set,
wherein the residual calculation unit updates the residual vector based on a union support set including the K selected supports and a sparse solution estimation result from the sparse solution estimator.

3. The subspace pursuit apparatus for compressive sensing reconstruction of claim 2, wherein the residual calculation unit generates an approximate residual vector, to be used in a support search process, by skipping a calculation of a Cholesky inverse matrix when the residual calculation unit updates the residual vector.

4. The subspace pursuit apparatus for compressive sensing reconstruction of claim 1, wherein the Cholesky inversion unit comprises a plurality of processing element (PE) groups each comprising a plurality of PEs,
wherein each of the PE groups generates a plurality of values in parallel when the Cholesky decomposition is performed,
wherein the plurality of values are generated as their dependencies in respective PE groups are resolved.

5. The subspace pursuit apparatus for compressive sensing reconstruction of claim 4, wherein the Cholesky decomposition for a last LSP of each PE group is skipped and is approximated based on the Cholesky decomposition for a first LSP of a corresponding PE group, so that a delay time is reduced and a next iteration is performed based on results of the sparse solution estimation process and the support search process.

6. The subspace pursuit apparatus for compressive sensing reconstruction of claim 5, wherein the Cholesky decomposition for a second LSP of each PE group is performed in parallel with the support search process of the next iteration for the next iteration.

7. The subspace pursuit apparatus for compressive sensing reconstruction of claim 4, wherein the Cholesky decomposition module implementing the Cholesky inversion unit and the sparse solution estimator comprises: the Gram matrix buffer connected to each of a plurality of operation modules of each PE group; a D buffer configured to store an output value of each PE group; and a buffer controller configured to store control operations of the Gram matrix buffer and the D buffer.

8. The subspace pursuit apparatus for compressive sensing reconstruction of claim 7, wherein each of the plurality of operation modules comprises internal buffers configured to store, in a location designated by the buffer controller, a decomposed matrix resulting from the Cholesky decomposition and an inverse matrix element value obtained by calculating an inverse matrix of the decomposed matrix.

9. A subspace pursuit method for compressive sensing reconstruction, comprising:
calculating, by a first inner product unit of type 1, a correlation between a residual vector stored in a residual calculation unit (RCU) and column vectors of a sensing matrix stored in a sensing matrix memory by calculating an inner product of the residual vector and the column vectors;
receiving, by a first sorting unit coupled to an output terminal of the first inner product unit, correlation values calculated by the first inner product unit to select K column vector indices having highest correlations, where K is a sparsity level;
calculating, by a second inner product unit coupled to the sensing matrix memory, a matrix for calculating a pseudo-inverse matrix required for solving a least-squares problem (LSP) during a sparse solution estimation process to store in a Gram matrix buffer;
performing, by a Cholesky inversion unit coupled to the Gram matrix buffer, a Cholesky decomposition of the matrix stored in the Gram matrix buffer and calculating an inverse of a decomposed matrix; and
estimating, by a sparse solution estimator, the sparse solution from a matrix value of the matrix stored in the Gram matrix buffer based on the inverse of the decomposed matrix.

10. The subspace pursuit method for compressive sensing reconstruction of claim 9, wherein estimating the sparse solution is performed by the sparse solution estimator based on the correlation calculated by the first inner product unit and an inverse matrix calculation result of the Cholesky inversion unit.

11. The subspace pursuit method for compressive sensing reconstruction of claim 10, further comprising:
calculating, by the residual calculation unit, the residual vector,
wherein calculating the residual vector is based on a union support set including K supports selected from a union of a newly selected supports set and an existing supports set and a sparse solution estimation result from the sparse solution estimator.

12. The subspace pursuit method for compressive sensing reconstruction of claim 11, wherein calculating the residual vector comprises:
calculating an approximate residual vector by skipping a calculation of a Cholesky inverse matrix.

13. The subspace pursuit method for compressive sensing reconstruction of claim 9, wherein each of a plurality of processing element (PE) groups for parallel Cholesky decompositions comprises a plurality of PEs,
wherein each of the PE groups generates a plurality of values in parallel by the plurality of PEs,
wherein the plurality of values are generated as their dependencies in respective PE groups are resolved.

14. The subspace pursuit method for compressive sensing reconstruction of claim 13, wherein the Cholesky decomposition for a last LSP of each PE group is skipped and is approximated based on the Cholesky decomposition for a first LSP of a corresponding PE group, so that a next iteration is performed based on results of the sparse solution estimation process and the support search process.

15. The subspace pursuit method for compressive sensing reconstruction of claim 14, wherein the Cholesky decomposition is performed such that the Cholesky decomposition for a second LSP of each PE group is performed in parallel with the support search process of the next iteration for the next iteration.

16. A subspace pursuit method for compressive sensing reconstruction, comprising:
(a) measuring a correlation between a sensing matrix and a residual vector;
(b) receiving correlation values to select K column vector indices having highest correlations to set a support set, where K is a sparsity level;
(c) pursuing a sparse vector by a least-squares method based on the support set;
(d) updating the residual vector based on a pursued sparse vector;
(e) estimating the sparse vector by the least-squares method based on a reset support set when the Cholesky decomposition being performed in parallel is completed after an iteration of operations (a) and (b) during an iteration process;
(f) setting K numbers having large sparse vectors pursued in the operation (e) as a support set;
(g) approximating the residual vector based on the support set including the K supports set in the operation (f); and
(h) sequentially repeating the operations (a), (b), (e), (f), and (g) while performing the Cholesky decomposition in parallel again until the residual vector is smaller than a threshold value.

17. The subspace pursuit method for compressive sensing reconstruction of claim 16, wherein the operation (e) is performed based on the correlation and the calculation result of the Cholesky inversion unit.

18. The subspace pursuit method for compressive sensing reconstruction of claim 16, wherein the operation (f) comprises:
selecting K most dominant supports from a union of a newly selected supports set and an existing supports set.

19. The subspace pursuit method for compressive sensing reconstruction of claim 16, wherein a plurality of values are generated in parallel by a plurality of processing element (PE) groups each comprising a plurality of PEs in a Cholesky inversion unit,
wherein the plurality of values are generated as their dependencies in respective PE groups are resolved.

20. The subspace pursuit method for compressive sensing reconstruction of claim 19, wherein the Cholesky decomposition for a last least-squares problem (LSP) of each PE group is skipped and is approximated based on the Cholesky decomposition for a first LSP of a corresponding PE group, so that a next iteration is performed based on results of an estimation process for the sparse vector or sparse solution and the support search process.
